(19) United States
(12) Patent Application Publication
(10) Pub. No.: US 2025/0259842 A1
(43) Pub. Date: Aug. 14, 2025

(54) COMPOUND SEMICONDUCTOR AND MANUFACTURING METHOD OF COMPOUND SEMICONDUCTOR

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: YUTA FURUMURA, Nisshin-shi (JP)

(21) Appl. No.: 18/974,126

(22) Filed: Dec. 9, 2024

(30) Foreign Application Priority Data
Feb. 9, 2024 (JP) 2024-018838

(51) Int. Cl. H01L 21/02; C30B 25/02; C30B 29/36; C30B 31/22; C30B 33/02; H10D 30/66; H10D 62/10; H10D 62/832

(52) U.S. Cl. CPC H01L 21/02694; C30B 25/02; C30B 29/36; C30B 31/22; C30B 33/02; H01L 21/02378; H01L 21/02529; H10D 30/66; H10D 62/111; H10D 62/8325

(57) ABSTRACT

A compound semiconductor has a crystal structure including a first element, a second element, a third element that partially substitutes for the first element and causes the compound semiconductor to have a first conductivity type, and a fourth element that partially substitutes for the second element and causes the compound semiconductor to have the first conductivity type.

### CROSS REFERENCE TO RELATED APPLICATION

The present application claims the benefit of priority from Japanese Patent Application No. 2024-018838 filed on Feb. 9, 2024. The entire disclosure of the above application is incorporated herein by reference.

### TECHNICAL FIELD

The present disclosure relates to a compound semiconductor and a manufacturing method of a compound semiconductor.

### BACKGROUND

There have been known manufacturing methods of semiconductor devices in which impurities are ion-implanted into predetermined regions of semiconductor layers to form a plurality of semiconductor regions in the semiconductor layers.

### SUMMARY

The present disclosure provides a compound semiconductor that has a crystal structure including a first element, a second element, a third element that partially substitutes for the first element and causes the compound semiconductor to have a first conductivity type, and a fourth element that partially substitutes for the second element and causes the compound semiconductor to have the first conductivity type.

The present disclosure also provides a semiconductor device that includes a semiconductor substrate, and a semiconductor region made of a compound semiconductor and disposed in a portion of the semiconductor substrate. The compound semiconductor has a crystal structure including a first element, a second element, a third element that partially substitutes for the first element and causes the compound semiconductor to have a first conductivity type, and a fourth element that partially substitutes for the second element and causes the compound semiconductor to have the first conductivity type.

The present disclosure also provides a manufacturing method of a compound semiconductor. The manufacturing method includes: forming a growth layer that has a crystal structure including a first element and a second element, and includes a third element as an impurity, the third element being capable of partially substituting for the first element and causing the compound semiconductor to have a first conductivity type; ion-implanting a fourth element into the growth layer, the fourth element being capable of partially substituting for the second element and causing the compound semiconductor to have the first conductivity type; and annealing the growth layer after the fourth element is ion-implanted to form the compound semiconductor.

The present disclosure further provides another manufacturing method of a compound semiconductor. The manufacturing method includes: ion-implanting a third element into a predetermined region in a semiconductor substrate that has a crystal structure including a first element and a second element, the third element being capable of partially substituting for the first element and causing the compound semiconductor to have a first conductivity type; ion-implanting a fourth element into the predetermined region into which the third element has been ion-implanted, the fourth element being capable of partially substituting for the second element and causing the compound semiconductor to have the first conductivity type; and annealing the semiconductor substrate after the third element and the fourth element are ion-implanted to form the compound semiconductor.

### BRIEF DESCRIPTION OF DRAWINGS

Objects, features and advantages of the present disclosure will become apparent from the following detailed description made with reference to the accompanying drawings. In the drawings:

FIG. 1 shows a cross-sectional view of a semiconductor device;

FIG. 2A is a diagram showing a state in which n-type impurities substitute at substitutional sites in a crystal structure of a compound semiconductor constituting a semiconductor device;

FIG. 2B is a diagram showing a state in which the n-type impurities are not introduced into the crystal structure of the compound semiconductor constituting the semiconductor device;

FIG. 3A is a diagram showing a state in which an n-type impurity substitutes at substitutional sites in a crystal structure of a compound semiconductor constituting a semiconductor device according to a comparative example;

FIG. 3B is a diagram showing a state in which the n-type impurity is not introduced into the crystal structure of the compound semiconductor constituting the semiconductor device according to the comparative example;

FIG. 4 is a flowchart showing a manufacturing method of a compound semiconductor according to a first embodiment; and

FIG. 5 is a flowchart showing a manufacturing method of a compound semiconductor according to a second embodiment.

### DETAILED DESCRIPTION

Next, a relevant technology is described only for understanding the following embodiments. When nitrogen is ion-implanted into a silicon carbide (SIC) semiconductor layer to form an n-type semiconductor region, carbon (carbon vacancies) in the SiC crystal is substituted with nitrogen, and the SiC semiconductor layer is made to have n-type. In order to increase an impurity concentration (n-type impurity concentration) of the SiC semiconductor layer, it is necessary to increase a concentration of nitrogen implanted in the ion implantation. However, if the concentration of nitrogen to be implanted is increased, crystal defects may occur during the ion implantation, which may deteriorate characteristics of a semiconductor device. Therefore, there is a need for a technique for adjusting an impurity concentration of a compound semiconductor while restricting deterioration of the characteristics of the semiconductor device.

A compound semiconductor according to a first aspect of the present disclosure has a crystal structure including a first element, a second element, a third element that partially substitutes for the first element and causes the compound semiconductor to have a first conductivity type, and a fourth element that partially substitutes for the second element and causes the compound semiconductor to have the first conductivity type.

In the compound semiconductor of the first aspect, both the first element and the second element constituting the crystal structure of the compound semiconductor are partially substituted with the third element and the fourth element, respectively. Therefore, compared with a compound semiconductor in which an impurity concentration is equal to that in the compound semiconductor of the first aspect and only lattice sites of the first element are substituted with the third element, the number of atomic vacancies (substitutional sites) of the first element is reduced, and a shortage of atomic vacancies of the first element is restricted. Thus, an impurity concentration of the third element ion-implanted into the compound semiconductor can be reduced, and crystal defects in the compound semiconductor can be restricted. As a result, deterioration in characteristics of a semiconductor device using the compound semiconductor can be restricted.

In the compound semiconductor according to the first aspect, a dopant concentration ratio of the third element to the fourth element in the crystal structure may be 1:9 to 9:1.

According to this configuration, it is possible to restrict a shortage of atomic vacancies for both the first element and the second element.

In the compound semiconductor according to the first aspect, the first element may be silicon (Si) and the second element may be carbon (C).

According to this configuration, crystal defects can be restricted in a high-voltage SiC semiconductor, and a semiconductor device having a high breakdown voltage and excellent electrical characteristics (for example, a low on-resistance) can be realized.

A semiconductor device according to a second aspect of the present disclosure includes a semiconductor substrate, and a semiconductor region made of a compound semiconductor and disposed in a portion of the semiconductor substrate. The compound semiconductor has a crystal structure includes a first element, a second element, a third element that partially substitutes for the first element and causes the compound semiconductor to have a first conductivity type, and a fourth element that partially substitutes for the second element and causes the compound semiconductor to have the first conductivity type.

In the semiconductor device according to the second aspect, a semiconductor region that is not made of the above-described compound semiconductor may be disposed in the semiconductor substrate. According to this configuration, for example, it is possible to dispose the semiconductor region made of the above-described compound semiconductor only in a specific region within the semiconductor substrate, avoiding a high-concentration impurity region that is in contact with an electrode. In such a case, it is not necessary to substitute a plurality of substitution sites with a plurality impurity elements when forming the high-concentration impurity region, and a manufacturing cost (manufacturing time) of the semiconductor device can be reduced.

A manufacturing method of a compound semiconductor according to a third aspect of the present disclosure includes: forming a growth layer that has a crystal structure including a first element and a second element, and includes a third element as an impurity, the third element being capable of partially substituting for the first element and causing the compound semiconductor to have a first conductivity type; ion-implanting a fourth element into the growth layer, the fourth element being capable of partially substituting for the second element and causing the compound semiconductor to have the first conductivity type; and annealing the growth layer after the fourth element is ion-implanted to form the compound semiconductor.

A manufacturing method of a compound semiconductor according to a fourth aspect of the present disclosure includes: ion-implanting a third element into a predetermined region in a semiconductor substrate that has a crystal structure including a first element and a second element, the third element being capable of partially substituting for the first element and causing the compound semiconductor to have a first conductivity type; ion-implanting a fourth element into the predetermined region into which the third element has been ion-implanted, the fourth element being capable of partially substituting for the second element and causing the compound semiconductor to have the first conductivity type; and annealing the semiconductor substrate after the third element and the fourth element are ion-implanted to form the compound semiconductor.

According to the manufacturing methods of the third aspect and the fourth aspect, the compound semiconductor can be made to have the first conductivity type by partially substituting lattice sites of the first element with the third element, and also by partially substituting lattice sites of the second element with the fourth element. The concentration of impurities ion-implanted into the compound semiconductor can be reduced, and crystal defects in the compound semiconductor can be restricted.

### Semiconductor Device

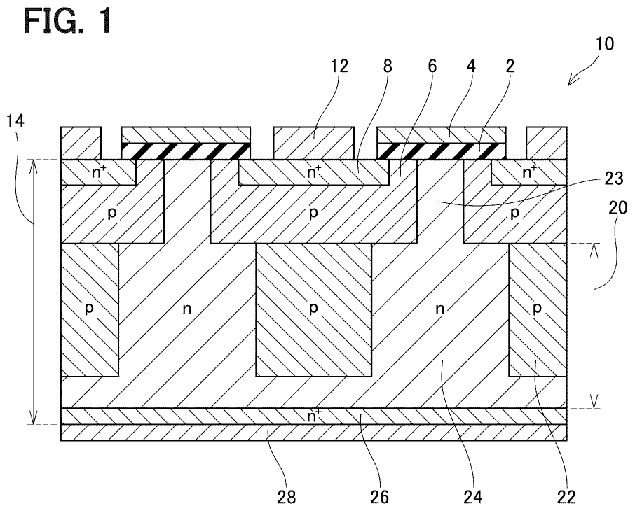

A semiconductor device 10 will be described with reference to FIG. 1. The semiconductor device 10 is a vertical semiconductor device and includes a semiconductor substrate 14, source electrodes 12 and gate electrodes 4 disposed on a front surface of the semiconductor substrate 14, and a drain electrode 28 disposed on a rear surface of the semiconductor substrate 14. The semiconductor substrate 14 is made of SiC. SiC is an example of a compound semiconductor. In the semiconductor device 10, source regions 8, body regions 6, a drift region 23, p-type column regions 22, n-type column regions 24, and a drain region 26 are formed by ion-implanting n-type or p-type impurities into the semiconductor substrate 14 that is n-type. The drift region 23 is a region of the semiconductor substrate 14 in which the source regions 8, the body regions 6, the p-type column regions 22, and the drain region 26 are not formed. In other words, the n-type column regions 24 are portions of the drift region 23.

The body regions 6 of p-type are disposed in a distributed manner on the front surface of the semiconductor substrate 14. In addition, the source regions 8 of n⁺ type are disposed on surfaces of the respective body regions 6. The source regions 8 are separated from the drift region 23 by the respective body regions 6. The source electrodes 12 are electrically connected to the respective source regions 8. The gate electrodes 4 are disposed above the surfaces of the body regions 6 separating the source regions 8 and the drift region 23 via respective gate insulating films 2. The semiconductor device 10 is a planar gate metal oxide semiconductor field effect transistor (MOSFET). The source regions 8 and the body regions 6 are formed by ion-implanting n-type or p-type impurity into the semiconductor substrate 14 from the front surface of the semiconductor substrate 14.

The drain region 26 of n⁺ type is disposed on the rear surface of the semiconductor substrate 14. The drain region 26 is formed by ion-implanting an n-type impurity into the semiconductor substrate 14 from the rear surface of the semiconductor substrate 14.

The p-type column regions 22 are disposed below the respective body regions 6. The p-type column regions 22 extend in a thickness direction of the semiconductor substrate 14 (that is, in a direction connecting the front surface and the rear surface). The n-type column regions 24 into which no impurity has been introduced are disposed between the p-type column regions 22. The p-type column regions 22 and the n-type column regions 24 form a superjunction structure 20. The superjunction structure 20 is formed in a middle portion in the thickness direction of the semiconductor substrate 14, that is, between the body regions 6 and the drain region 26. The p-type column regions 22 are formed by an ion-implanting p-type impurity into the semiconductor substrate 14 from the front surface of the semiconductor substrate 14. As will be described in detail later, in the n-type column regions 24 (that is, in the drift region 23), some of silicon (Si) vacancies are substituted with phosphorus (P) and some of carbon (C) vacancies are substituted with nitrogen (N).

In the semiconductor device 10, when a voltage exceeding a threshold voltage is applied to the gate electrodes 4, inversion layers (channels) are formed on the surfaces of the body regions 6 facing the gate electrodes 4. Electrons supplied from the source electrodes 12 to the source regions 8 pass through the inversion layers and are supplied to the drift region 23. The electrons supplied to the drift region 23 move toward the drain region 26 and are discharged from the drain electrode 28. In other words, the semiconductor device 10 is turned on. When the application of voltage to the gate electrodes 4 is stopped (that is, when the voltage applied to the gate electrode 4 is made lower than the threshold voltage), the inversion layers formed in the body regions 6 disappear, and the supply of electrons from the source regions 8 to the drift region 23 stops. In other words, the semiconductor device 10 is turned off. The semiconductor device 10 is a normally-off MOSFET that turns on when a voltage exceeding the threshold voltage is applied to the gate electrodes 4.

As described above, the semiconductor device 10 has the superjunction structure 20 formed in the semiconductor substrate 14. Therefore, when the semiconductor device 10 is turned off, depletion layers extend from interfaces between the p-type column regions 22 and the n-type column regions 24 into the p-type column regions 22 and also into the n-type column regions 24. In the semiconductor device 10, a length in a width direction (that is, the left-right direction in FIG. 1) that is perpendicular to the thickness direction and an impurity concentration of each of the p-type column regions 22, and a length in the width direction and an impurity concentration of each of the n-type column regions 24 are controlled, thereby ensuring a charge balance condition between the p-type column regions 22 and the n-type column regions 24. While the semiconductor device 10 is off, the semiconductor substrate 14 (that is, the portion in which the superjunction structure 20 is formed) can be almost completely depleted. Therefore, the semiconductor device 10 has a high breakdown voltage.

### Crystal Structure of N-type Column Regions

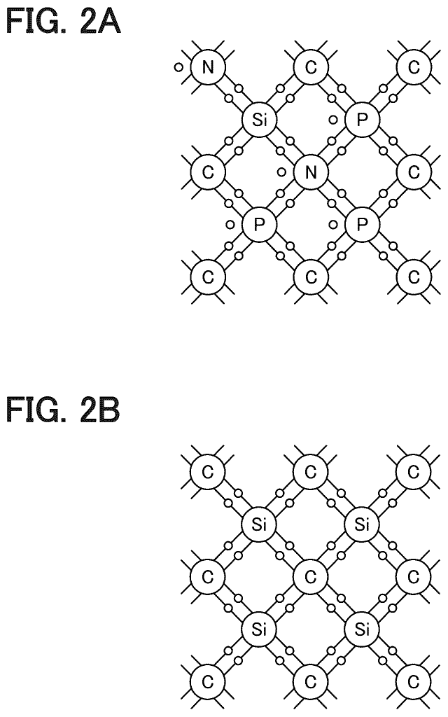

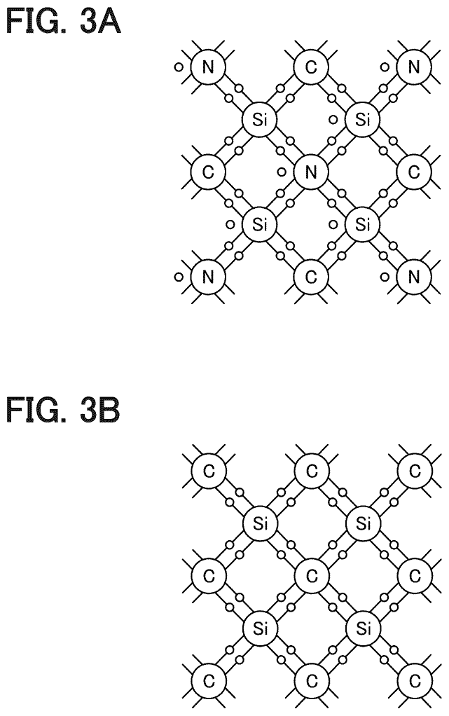

The crystal structure of the n-type column regions 24 (that is, the drift region 23) will be described with reference to FIGS. 2A, 2B, 3A, and 3B. FIG. 2A and FIG. 2B show a part of the crystal structure of the n-type column regions 24 of the semiconductor device 10. FIG. 3A and FIG. 3B show a part of a crystal structure of n-type column regions of a semiconductor device of a comparative example. FIG. 2A and 3A show states where one or more n-type impurities are substituted at substitutional sites, while FIG. 2B and FIG. 3B show states where n-type impurities are not introduced.

As shown in FIG. 2A and FIG. 2B, in the semiconductor device 10, silicon vacancies are substituted with phosphorus, and carbon vacancies are substituted with nitrogen. In FIG. 2A, three silicon vacancies are substituted with phosphorus and two carbon vacancies are substituted with nitrogen. The n-type column regions 24 are made to have n-type conductivity by substituting silicon vacancies with phosphorus. The n-type column region 24 are made to have n-type conductivity also by substituting carbon vacancies with nitrogen.

In the semiconductor device 10, a ratio of a phosphorus concentration (atoms/cm ⁻³) to a nitrogen concentration (atoms/cm⁻³) in the n-type column regions 24 (that is, a dopant concentration ratio) is adjusted to be 1:9 to 9:1. Furthermore, semiconductor regions (the n-type column regions 24) in which silicon vacancies are substituted with phosphorus and carbon vacancies are substituted with nitrogen are disposed in portions of the semiconductor substrate 14. In other words, the crystal structure in which silicon vacancies are substituted with phosphorus and carbon vacancies are substituted with nitrogen (that is, the crystal structure shown in FIG. 2A) is present only in the n-type column regions 24 and is not present in, for example, the source regions 8, the body regions 6, the p-type column regions 22, and the drain region 26.

As shown in FIG. 3A and FIG. 3B, in the semiconductor device of the comparative example, only carbon vacancies are substituted with nitrogen, and silicon vacancies are not substituted. In FIG. 3A, five carbon vacancies are substituted with nitrogen. In the semiconductor device of the comparative example, the n-type column regions are made to have n-type conductivity by substituting carbon vacancies with nitrogen.

As described above, in both the semiconductor device 10 and the semiconductor device of the comparative example, five vacancies are substituted with impurities (phosphorus and nitrogen). Therefore, impurity concentrations in the n-type column regions of the semiconductor device 10 and the semiconductor device of the comparative example are approximately equal to each other. However, while two carbon vacancies are substituted with nitrogen in the semiconductor device 10, five carbon vacancies are substituted with nitrogen in the semiconductor device of the comparative example. Therefore, in the case of the semiconductor device of the comparative example, when nitrogen is ion-implanted into the SiC semiconductor, carbon vacancies tend to become insufficient, so that it is necessary to make the doping concentration (dose amount) of nitrogen higher than that of the semiconductor device 10. As a result, the semiconductor device of the comparative example is prone to crystal defects in the SiC semiconductor. In other words, the semiconductor device 10 is less prone to crystal defects in the SiC semiconductor (in the n-type column regions 24) than the semiconductor device of the comparative example.

Other advantages of the semiconductor device 10 will now be described. As described above, the semiconductor device 10 is less prone to crystal defects in the SiC semiconductor compared to the semiconductor device of the comparative example. As a result, the semiconductor device 10 can restrict the occurrence of deterioration in electrical characteristics, such as an increase in on-resistance. That is, the semiconductor device 10 can adjust the impurity concentration in the n-type column regions 24 in the semiconductor substrate 14 while restricting specific deterioration of the device. Moreover, nitrogen has a higher ionization energy than phosphorus. Therefore, the ion implantation of nitrogen requires a lower beam current and a longer ion implantation time than the ion implantation of phosphorus. When the ion implantation time becomes longer, the replacement cycle of parts (consumable parts) of the manufacturing equipment (for example, an ion implantation device) becomes shorter. As a result, the manufacturing cost of the semiconductor device increases. The semiconductor device 10 can extend the replacement cycle of parts in the manufacturing equipment, and can also reduce the manufacturing cost.

### Manufacturing Method of First Embodiment

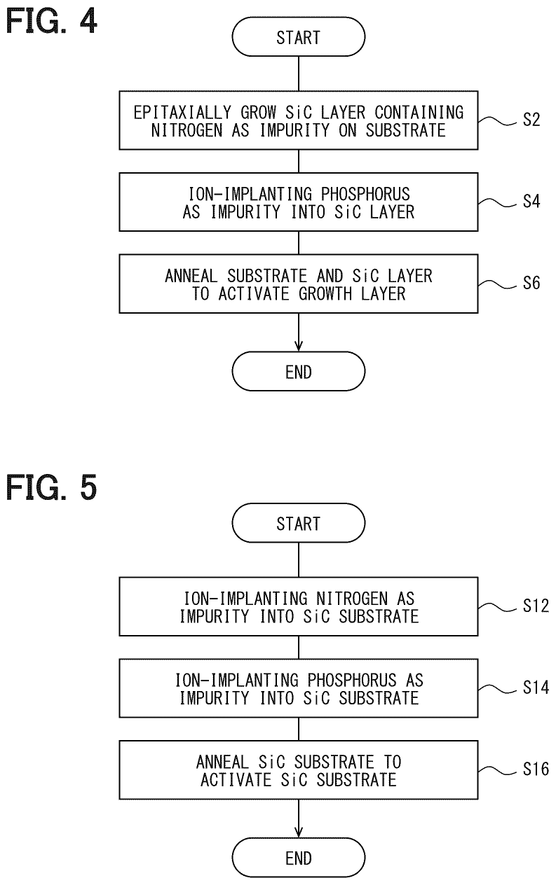

A manufacturing method of the semiconductor device 10 according to a first embodiment will now be described with reference to FIG. 4. As described above, the source regions 8, the body regions 6, the drain region 26 and the p-type column regions 22 are formed by ion-implanting n-type or p-type impurities into the semiconductor substrate 14. These ion implantation techniques are well known and therefore will not be described here. In the following, only the manufacturing method of the n-type column regions 24 (that is, the drift region 23) will be described.

First, a silicon source gas, a carbon source gas, and a nitrogen source gas are supplied onto a substrate, and a SiC growth layer containing nitrogen as an impurity is epitaxially grown on the substrate (film formation process: S2). By supplying the nitrogen source gas, an n-type SiC growth layer in which carbon vacancies are substituted with nitrogen is formed.

Next, phosphorus is ion-implanted as an impurity into the SiC growth layer (ion implantation process: S4). A concentration of the nitrogen source gas and a concentration of phosphorus (doping concentration) are adjusted so that the concentrations of phosphorus and nitrogen contained in the SiC growth layer are 1:9 to 9:1.

Next, the substrate and the SiC growth layer are heated to anneal the SiC growth layer (annealing process: S6). In the annealing process, the substrate and the SiC growth layer are heated to a temperature at which the phosphorus and nitrogen are activated. By carrying out the annealing process, phosphorus substitutes for silicon vacancies, and an n-type semiconductor (n-type SiC semiconductor) having the crystal structure shown in FIG. 2A is formed.

According to the above-described manufacturing method, it is possible to restrict a shortage of carbon vacancies, as compared with, for example, an n-type SiC semiconductor in which only carbon vacancies are substituted with nitrogen. Therefore, the doping concentration during ion implantation can be restricted, and the occurrence of crystal defects in the n-type column regions 24 (that is, the drift region 23) can be restricted. In the present embodiment, carbon is an example of a first element, silicon is an example of a second element, nitrogen is an example of a third element, and phosphorus is an example of a fourth element. Note that, in the present disclosure, the first element, the second element, the third element, and the fourth element are different elements from each other.

As a modification of the present embodiment, a silicon source gas, a carbon source gas, and a phosphorus source gas may be used in the film formation process, and nitrogen ions may be implanted in the ion implantation process. In this case as well, by carrying out the annealing process, the n-type semiconductor (n-type SiC semiconductor) having the crystal structure shown in FIG. 2A can be formed. In this modification, silicon is an example of the first element, carbon is an example of the second element, phosphorus is an example of the third element, and nitrogen is an example of the fourth element.

### Manufacturing Method of Second Embodiment

A manufacturing method of the semiconductor device 10 according to a second embodiment will be described with reference to FIG. 5. In the present embodiment as well, only the manufacturing method of the n-type column regions 24 (that is, the drift region 23) will be described.

First, a SiC substrate (semiconductor substrate) of i-type is prepared, and nitrogen is ion-implanted as an impurity into a predetermined region in the SiC substrate (first ion implantation process: S12). Next, phosphorus is ion-implanted as an impurity into the SiC substrate (second ion implantation process: S14). In the second ion implantation process, phosphorus is ion-implanted into the predetermined region into which nitrogen has been implanted in the first ion implantation process. In the first and second ion implantation processes, the concentrations (doping concentrations) of nitrogen and phosphorus are adjusted to be 1:9 to 9:1.

Next, the SiC substrate is annealed (annealing process: S16). In the annealing process, the SiC substrate is heated to a temperature at which phosphorus and nitrogen are activated. By carrying out the annealing process, phosphorus substitutes for silicon vacancies and nitrogen substitutes for carbon vacancies, and an n-type semiconductor (n-type SiC semiconductor) having the crystal structure shown in FIG. 2A is formed.

Also in the above-described manufacturing method, it is possible to restrict a shortage of carbon vacancies, as compared with, for example, an n-type SiC semiconductor in which only carbon vacancies are substituted with nitrogen. Therefore, in the above-described manufacturing method, the doping concentration during the ion implantation can be restricted, and the occurrence of crystal defects in the n-type column regions 24 (that is, the drift region 23) can be restricted. In the present embodiment, carbon is an example of the first element, silicon is an example of the second element, nitrogen is an example of the third element, and phosphorus is an example of the fourth element.

In the present embodiment, the order of S12 and S14 is optional, and S12 may be performed after S14. In this case, S14 is the first ion implantation process, S12 is the second ion implantation process, silicon is an example of the first element, carbon is an example of the second element, phosphorus is an example of the third element, and nitrogen is an example of the fourth element.

In S12, a SiC substrate of n-type or p-type may be used instead of the SiC substrate of i-type. When a SiC substrate of n-type is used in S12, a SiC substrate having a lower impurity concentration than the desired impurity concentration (the impurity concentration of the n-type column regions 24) is used.

In the above-described embodiments, instead of SiC, a compound semiconductor such as gallium nitride (GaN) or gallium arsenide (GaAs) may be used. That is, in the present disclosure, any type of compound semiconductor may be used as long as it has two or more substitution sites.

In the above-described embodiments, the semiconductor device in which the crystal structure of the n-type column regions is substituted with two types of impurities that make the compound semiconductor have n-type conductivity has been described. However, the present disclosure can also be applied to a semiconductor device in which a crystal structure of p-type column region is substituted with two types of impurities that make a compound semiconductor have p-type conductivity. The present disclosure can also be applied to a semiconductor device in which a crystal structure of n-type column regions is substituted with two types of impurities that make a compound semiconductor have n-type conductivity, and a crystal structure of p-type column regions is substituted with two types of impurities that make the compound semiconductor have p-type conductivity.

When both the n-type column regions and the p-type column regions are each substituted with two types of impurities, both the n-type column regions and the p-type column regions may be manufactured by the method described in the first embodiment. In another example, both the n-type column regions and the p-type column regions may be manufactured by the method described in the second embodiment. In another example, the n-type column regions or the p-type column regions may be manufactured by the method described in the first embodiment, and the other of the n-type column regions or the p-type column regions may be manufactured by the method described in the second embodiment.

The present disclosure can also be applied to semiconductor regions other than the n-type column regions and p-type column regions (for example, a body region).

In the above-described embodiments, a planar gate type MOSFET has been described. However, the present disclosure can be applied to various semiconductor devices, and can also be used in, for example, trench gate MOSFETS, planar gate or trench gate insulated gate bipolar transistors (IGBTs), and the like. The present disclosure can also be applied to semiconductor devices that do not have a superjunction structure.

Although the embodiments of the present disclosure have been described in detail above, these are merely examples and do not limit the scope of the claims. The techniques described in the present description include various modifications of the specific examples illustrated above. In addition, the technical elements described in the present specification or the drawings exhibit technical usefulness alone or in various combinations, and are not limited to the combinations described in the claims at the time of filing. In addition, the techniques illustrated in the present specification or drawings can achieve multiple purposes at the same time, and achieving one of the purposes itself has technical usefulness.

What is claimed is:

1. A compound semiconductor having a crystal structure, the crystal structure comprising:
a first element;
a second element;
a third element that partially substitutes for the first element and causes the compound semiconductor to have a first conductivity type; and
a fourth element that partially substitutes for the second element and causes the compound semiconductor to have the first conductivity type.

2. The compound semiconductor according to claim 1, wherein
in the crystal structure, a dopant concentration ratio of the third element to the fourth element is 1:9 to 9:1.

3. The compound semiconductor according to claim 1, wherein the first element is silicon and the second element is carbon.

4. A semiconductor device comprising:
a semiconductor substrate; and
a semiconductor region made of a compound semiconductor and disposed in a portion of the semiconductor substrate, wherein
the compound semiconductor has a crystal structure including:
a first element;
a second element;
a third element that partially substitutes for the first element and causes the compound semiconductor to have a first conductivity type; and
a fourth element that partially substitutes for the second element and causes the compound semiconductor to have the first conductivity type.

5. A manufacturing method of a compound semiconductor, comprising:
forming a growth layer that has a crystal structure including a first element and a second element, and includes a third element as an impurity, the third element being capable of partially substituting for the first element and causing the compound semiconductor to have a first conductivity type;
ion-implanting a fourth element into the growth layer, the fourth element being capable of partially substituting for the second element and causing the compound semiconductor to have the first conductivity type; and
annealing the growth layer after the fourth element is ion-implanted to form the compound semiconductor.

6. A manufacturing method of a compound semiconductor, comprising:
ion-implanting a third element into a predetermined region in a semiconductor substrate that has a crystal structure including a first element and a second element, the third element being capable of partially substituting for the first element and causing the compound semiconductor to have a first conductivity type;
ion-implanting a fourth element into the predetermined region into which the third element has been ion-implanted, the fourth element being capable of partially substituting for the second element and causing the compound semiconductor to have the first conductivity type; and
annealing the semiconductor substrate after the third element and the fourth element are ion-implanted to form the compound semiconductor.
